(19) United States
(12) Patent Application Publication
(10) Pub. No.: US 2026/0282828 A1
(43) Pub. Date: Sep. 17, 2026

(54) ELECTROSTATIC CHUCK WITH CONDUCTIVE MESH

(71) Applicant: Applied Materials, Inc., Santa Clara, CA (US)

(72) Inventors: Jian LI, Fremont, CA (US); Ganesh BALASUBRAMANIAN, Fremont, CA (US); Juan C. ROCHA, San Carlos, CA (US); Arvinder Manmohan Singh CHADHA, San Jose, CA (US); Abhishek Kumar Verma, Santa Clara, CA (US); Kallol Bera, Milpitas, CA (US)

(21) Appl. No.: 19/077,287

(22) Filed: Mar. 12, 2025

(51) Int. Cl. H01L 21/683; H01J 37/32

(52) U.S. Cl. CPC H10P 72/722; H01J 37/32715; H01J 2237/2007

(57) ABSTRACT

The present disclosure describes a filter assembly for a heater line of a processing chamber. The filter assembly includes a first impedance producing element, a first air core inductor, and a second air core inductor. The first impedance producing element includes a first conductive lead and a second conductive lead wound around a first toroid shaped core. A first end of the first conductive lead and a first end of the second conductive lead are coupled to an output of an electric device. The first air core inductor is electrically connected with the first conductive lead. The second air core inductor is electrically connected with the second conductive lead.

### FIELD

Embodiments described herein generally relate to plasma processing chambers and electrostatic chucks used in semiconductor manufacturing.

### BACKGROUND

### Description of the Related Art

Reliably producing high aspect ratio features is one of the key technology challenges for the next generation of very large scale integration (VLSI) and ultra large scale integration (ULSI) of semiconductor devices. One method of forming high aspect ratio features uses a plasma assisted etching process, such as a reactive ion etch (RIE) plasma process, to form high aspect ratio openings in a material layer, such as a dielectric layer, of a substrate. In a typical RIE plasma process, a plasma is formed in an RIE processing chamber and ions from the plasma are accelerated towards a surface of a substrate to form openings in a material layer disposed beneath a mask layer formed on the surface of the substrate.

An electrostatic chuck (ESC) assembly within the plasma processing chamber supports and/or secures the substrate during the process. The support may be positioned on a surface of a support of the ESC assembly. The ESC assembly may also include one or more electrodes positioned within the support. When direct current (DC) power is directed to the electrodes, the electrodes produce electric fields that generate an electrostatic force that secures the substrate on the support, which prevents the substrate from shifting or moving during the process.

Due to the shape and/or arrangement of the electrodes, however, the electric fields produced by the electrodes may extend beyond the edge of the substrate and into the plasma above the substrate. As a result, the electric fields cause a higher sheath voltage and higher ion bombardment that damages the ESC surface around the edge of the substrate. The damage may cause the ESC surface to flake or break off, leaving residue in the processing chamber.

### SUMMARY

The present disclosure describes an electrostatic chuck with a conductive ring. According to an embodiment, an electrostatic chuck includes a substrate support, a first electrode positioned within the substrate support, and a conductive ring positioned within the substrate support. The substrate support includes a surface, and the surface includes (i) a first portion arranged to support a substrate and (ii) a second portion positioned around the first portion. The first electrode produces a first electric field. The conductive ring is positioned between the second portion of the surface and the first electrode, and the conductive ring shields the second portion from the first electric field.

According to another embodiment, a method includes supporting, by a first portion of a surface of a substrate support, a substrate. The surface includes a second portion positioned around the first portion. The method also includes producing, by a first electrode positioned within the substrate support, a first electric field and shielding, by a conductive ring positioned within the substrate support and between the second portion of the surface and the first electrode, the second portion from the first electric field.

According to another embodiment, a processing chamber includes a substrate support positioned within a process volume defined by a chamber body, a first electrode positioned within the substrate support, a second electrode positioned within the substrate support, and a conductive ring positioned within the substrate support. The substrate support includes a surface that includes (i) a first portion arranged to support a substrate within the process volume and (ii) a second portion positioned around the first portion. The first electrode produces a first electric field, and the second electrode produces a second electric field. The conductive ring is positioned between the second portion of the surface and the first and second electrodes. The conductive ring shields the second portion from the first and second electric fields.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic cross-sectional view of an example processing chamber, according to one embodiment.

FIG. 2 illustrates a cross-section of an example substrate support in the processing chamber of FIG. 1, according to one embodiment.

FIG. 3 illustrates a cross-section of an example substrate support in the processing chamber of FIG. 1, according to one embodiment.

FIG. 4 illustrates a cross-section of an example substrate support in the processing chamber of FIG. 1, according to one embodiment.

FIG. 5A illustrates an example substrate support in the processing chamber of FIG. 1, according to one embodiment.

FIG. 5B illustrates example components of a substrate support in the processing chamber of FIG. 1, according to one embodiment.

FIG. 5C illustrates example components of a substrate support in the processing chamber of FIG. 1, according to one embodiment.

FIG. 6 illustrates a cross-section of a portion of an example substrate support in the processing chamber of FIG. 1, according to one embodiment.

FIG. 7 illustrates an example conductive ring of a substrate support in the processing chamber of FIG. 1, according to one embodiment.

FIG. 8A illustrates a cross-section of a portion of an example substrate support in the processing chamber of FIG. 1, according to one embodiment.

FIG. 8B illustrates a cross-section of a portion of an example substrate support in the processing chamber of FIG. 1, according to one embodiment.

FIG. 8C illustrates a cross-section of a portion of an example substrate support in the processing chamber of FIG. 1, according to one embodiment.

FIG. 8D illustrates a cross-section of a portion of an example substrate support in the processing chamber of FIG. 1, according to one embodiment.

FIG. 8E illustrates a cross-section of a portion of an example substrate support in the processing chamber of FIG. 1, according to one embodiment.

FIG. 8F illustrates a cross-section of a portion of an example substrate support in the processing chamber of FIG. 1, according to one embodiment.

FIG. 9A illustrates a cross-section of a portion of an example substrate support in the processing chamber of FIG. 1, according to one embodiment.

FIG. 9B illustrates a cross-section of a portion of an example substrate support in the processing chamber of FIG. 1, according to one embodiment.

FIG. 9C illustrates a cross-section of a portion of an example substrate support in the processing chamber of FIG. 1, according to one embodiment.

FIG. 9D illustrates a cross-section of a portion of an example substrate support in the processing chamber of FIG. 1, according to one embodiment.

FIG. 9E illustrates a cross-section of a portion of an example substrate support in the processing chamber of FIG. 1, according to one embodiment.

FIG. 9F illustrates a cross-section of a portion of an example substrate support in the processing chamber of FIG. 1, according to one embodiment.

FIG. 9G illustrates a cross-section of a portion of an example substrate support in the processing chamber of FIG. 1, according to one embodiment.

FIG. 10 is a flowchart of an example method performed by the processing chamber of FIG. 1, according to one embodiment.

FIG. 11 is a schematic cross sectional view of a process chamber configured according to various embodiments of the present disclosure

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure describes an electrostatic chuck (ESC) assembly that includes a conductive ring that shields portions of the ESC from electric fields produced by one or more electrodes in the ESC. Generally, the conductive ring is positioned within the substrate support in the ESC between the electrodes that produce the electric fields and the top surface of the substrate support that supports the substrate. The conductive ring may extend beyond the edges of the electrodes and closer to a side edge of the substrate support. As a result, the conductive ring provides a barrier that shields the portion of the top surface of the substrate support that extends beyond the edge of the substrate from the electric fields produced by the electrodes.

In some embodiments, the conductive ring provides several technical advantages. For example, the conductive ring reduces the magnitude of the electric field at and above the portion of the top surface of the substrate support that extends beyond the edge of the substrate. As a result, the conductive ring reduces or prevents damage to the substrate support.

Embodiments described herein are applicable for use in all types of plasma assisted or plasma enhanced processing chambers and also for methods of plasma assisted or plasma enhanced processing of a substrate.

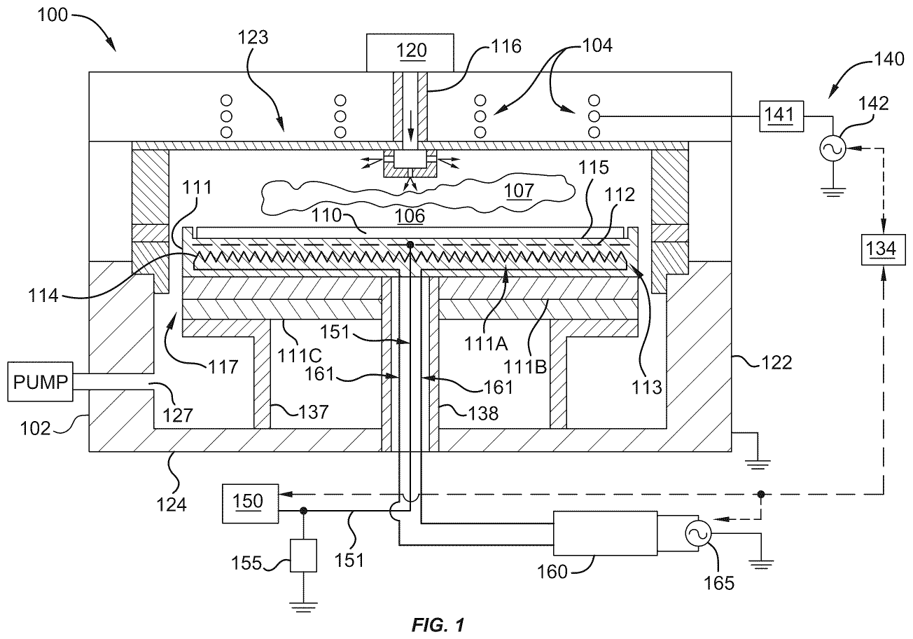

FIG. 1 is a schematic cross-sectional view of a processing chamber 100 configured to perform a plasma process within a processing volume 106 of the process chamber 100 by use of a source assembly 140, according to one embodiment. In this embodiment, the processing chamber 100 is a plasma processing chamber, such as a reactive ion etch (RIE) plasma chamber. In some other embodiments, the processing chamber is a plasma-enhanced deposition chamber, for example a plasma-enhanced chemical vapor deposition (PECVD) chamber, a plasma enhanced physical vapor deposition (PEPVD) chamber, or a plasma-enhanced atomic layer deposition (PEALD) chamber. In some other embodiments, the processing chamber is a plasma treatment chamber, or a plasma based ion implant chamber, for example a plasma doping (PLAD) chamber. As shown in FIG. 1, the processing chamber 100 includes a source assembly 140 that includes an inductively coupled plasma (ICP) source electrically coupled to a radio frequency (RF) power supply 142 through an RF matching circuit 141. In other embodiments, the source assembly 140 is a capacitively coupled plasma (CCP) source, such as a source electrode (not shown) disposed in the processing volume 106 facing the substrate support 111, wherein the source electrode is electrically coupled to an RF power supply (not shown).

The processing chamber 100 includes a chamber body 102 which includes a chamber lid 123, one or more sidewalls 122, and a chamber base 124 which define a processing volume 106. A gas inlet 116 disposed through the chamber lid 123 is used to provide one or more processing gases to the processing volume 106 from a processing gas source 120 in fluid communication therewith. The power supply 142 is configured to ignite and maintain a processing plasma 107 from the processing gases using one or more inductive coils 104 disposed proximate to the chamber lid 123 outside of the processing volume 106. The processing volume 106 is fluidly coupled to one or more dedicated vacuum pumps, through a vacuum outlet 127, which maintain the processing volume 106 at sub-atmospheric conditions and evacuate processing gases and/or other gases therefrom. A substrate support assembly 117 is disposed in the processing volume 106 and on a support shaft 138 sealingly extending through the chamber base 124.

The substrate 110 is loaded into and removed from the processing volume 106 through an opening (not shown) in one of the one or more sidewalls 122, which is sealed with a door or a valve (not shown) during plasma processing of the substrate 110. Herein, the substrate 110 is transferred to and from a receiving surface 115 (e.g., substrate supporting surface) of the substrate support 111, which can include an ESC substrate support 111A using a lift pin system (not shown).

The substrate support 111 includes a support base 111B and the ESC substrate support 111A that is thermally coupled to and disposed on the support base 111B. The support base 111B is electrically isolated from the chamber base 124 by an insulator plate 111C and a ground plate 137 that is interposed between the insulator plate 111C and the chamber base 124. Typically, the support base 111B is used to regulate the temperatures of the ESC substrate support 111A and the substrate 110 disposed on the ESC substrate support 111A during substrate processing. In some embodiments, the support base 111B includes one or more cooling channels (not shown) disposed therein that are fluidly coupled to, and in fluid communication with, a coolant source (not shown), such as a refrigerant source or water source having relatively high electrical resistance. Herein, the support base 111B is formed of a corrosion resistant thermally conductive material, such as a corrosion resistant metal, for example aluminum, aluminum alloy, or stainless steel and is coupled to the substrate support with an adhesive or by mechanical means.

Typically, the ESC substrate support 111A is formed of a dielectric material, such as a bulk sintered ceramic material, such as a corrosion resistant metal oxide or metal nitride material, for example aluminum oxide (Al₂O₃), aluminum nitride (AlN), titanium oxide (TiO), titanium nitride (TiN), yttrium oxide (Y₂O₃), mixtures thereof, or combinations thereof. In some embodiments, the ESC substrate support 111A further includes a biasing electrode 112 embedded in the dielectric material. In one configuration, the biasing electrode 112 is a chucking pole used to secure (chuck) the substrate 110 to the receiving surface 115 of the ESC substrate support 111A and to bias the substrate 110 with respect to the processing plasma 107. Typically, the biasing electrode 112 is formed of one or more electrically conductive parts, such as one or more metal meshes, foils, plates, or combinations thereof. Herein, the biasing electrode 112 is electrically coupled to a high voltage module 155 which provides a chucking voltage thereto, such as static DC voltage between about −5000 V and about 5000 V, using an electrical conductor, such as the transmission line 151.

The ESC substrate support 111A includes a heater element 113 (which may also be referred to as a heater), such as a resistive heating element, embedded in the dielectric material of the ESC substrate support 111A. The heater element 113 is used to generate heat within the ESC substrate support 111A due to resistive heating created by the delivery of AC power through one or more conductive elements 114, which are embedded within the material used to form the ESC substrate support 111A, by use of an AC power supply 165. In one embodiment, the one or more conductive elements 114 are spaced a distance from the biasing electrode 112, and thus are not directly connected to the biasing electrode 112. The heater element 113 may include a plurality of heating zones formed using multiple conductive elements 114. Each heating zone may generate and apply a different amount of heat to a different portion of the ESC substrate support 11A and/or the substrate 110.

A filter assembly 160 is disposed between the AC power supply 165 and the one or more conductive elements 114 to prevent RF leakage from the biasing electrode 112 to the one or more conductive elements 114 from flowing into the AC power supply 165 and damaging its internal components and/or creating an unsafe condition for a user of the processing tool.

The biasing electrode 112 is spaced apart from the substrate receiving surface 115 of the ESC substrate support 111A, and thus from the substrate 110, by a layer of dielectric material of the ESC substrate support 111A. Typically, the layer of dielectric material has a thickness between about 0.1 mm and about 1 mm, such as between about 0.1 mm and about 0.5 mm, for example about 0.3 mm. Herein, the biasing electrode 112 is electrically coupled to the power generator 150 using the external conductor, such as the transmission line 151. The power generator 150 can be a direct current (DC) power generator, a low frequency RF power generator, or a shaped pulsed DC bias power generator. The dielectric material and layer thickness formed between biasing electrode 112 and the substrate receiving surface 115 can be selected so that the capacitance of the layer of dielectric material is between about 5 nF and about 12 nF, such as between about 7 and about 10 nF, for example.

The processing chamber 100 further includes a system controller 134. The system controller 134 herein includes a central processing unit (CPU), a memory, and support circuits. The system controller 134 is used to control the process sequence used to process the substrate 110. The CPU is a general purpose computer processor configured for use in an industrial setting for controlling processing chamber and sub-processors related thereto. The memory described herein may include random access memory, read only memory, floppy or hard disk drive, or other suitable forms of digital storage, local or remote. The support circuits are conventionally coupled to the CPU and comprise cache, clock circuits, input/output subsystems, power supplies, and the like, and combinations thereof. Software instructions and data can be coded and stored within the memory for instructing a processor within the CPU. A program (or computer instructions) readable by the system controller 134 determines which tasks are performable by the components in the processing chamber 100. Preferably, the program, which is readable by the system controller 134, includes code, which when executed by the processor, perform tasks relating to the monitoring and execution of the electrode biasing scheme described herein. The program will include instructions that are used to control the various hardware and electrical components within the processing chamber 100 to perform the various process tasks and various process sequences used to implement the electrode biasing scheme described herein.

The CPU is any electronic circuitry, including, but not limited to one or a combination of microprocessors, microcontrollers, application specific integrated circuits (ASIC), application specific instruction set processor (ASIP), and/or state machines, that communicatively couples to the memory. The CPU may be 8-bit, 16-bit, 32-bit, 64-bit or of any other suitable architecture. The CPU may include an arithmetic logic unit (ALU) for performing arithmetic and logic operations, processor registers that supply operands to the ALU and store the results of ALU operations, and a control unit that fetches instructions from memory and executes them by directing the coordinated operations of the ALU, registers and other components. The CPU may include other hardware that operates software to control and process information. The CPU executes software stored on the memory to perform any of the functions described herein. The CPU controls the operation and administration of the processing chamber 100 by processing information (e.g., information received from sensors and/or the memory). The CPU is not limited to a single processing device and may encompass multiple processing devices contained in the same device or computer or distributed across multiple devices or computers. The CPU is considered to perform a set of functions or actions if the multiple processing devices collectively perform the set of functions or actions, even if different processing devices perform different functions or actions in the set.

The memory may store, either permanently or temporarily, data, operational software, or other information for the CPU. The memory may include any one or a combination of volatile or non-volatile local or remote devices suitable for storing information. For example, the memory may include random access memory (RAM), read only memory (ROM), magnetic storage devices, optical storage devices, or any other suitable information storage device or a combination of these devices. The software represents any suitable set of instructions, logic, or code embodied in a computer-readable storage medium. For example, the software may be embodied in the memory, a disk, a CD, or a flash drive. In particular embodiments, the software may include an application executable by the CPU to perform one or more of the functions described herein. The memory is not limited to a single memory and may encompass multiple memories contained in the same device or computer or distributed across multiple devices or computers. The memory is considered to store a set of data, operational software, or information if the multiple memories collectively store the set of data, operational software, or information, even if different memories store different portions of the data, operational software, or information in the set.

In some embodiments, the substrate support 111 includes a conductive ring positioned between the electrode 112 and a top surface of the substrate support 111. The conductive ring shields portions of the top surface of the substrate support 111 from the electric field generated by the electrode 112. As a result, the conductive ring reduces the magnitude of the electric field at these portions of the top surface, which reduces the ion bombardment and resulting damage at these portions.

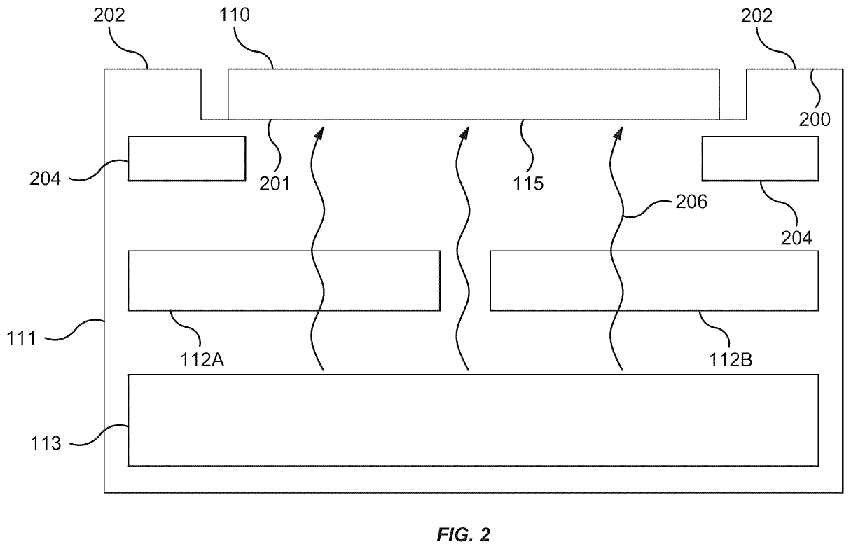

FIG. 2 illustrates a cross-section of an example substrate support 111 in the processing chamber 100 of FIG. 1, according to one embodiment. As seen in FIG. 2, the substrate support 111 includes top surface 200 that includes a first portion 201 and a second portion 202. The first portion 201 includes the receiving surface 115 that supports the substrate 110 on the substrate support 111. The second portion 202 is positioned around the edge of the first portion 101. As a result, the first portion 201 and the second portion 202 may be concentric portions with the first portion 201 forming an inner area of the top surface 200 and with the second portion 202 forming an outer area of the top surface 200 around the inner area.

The heater element 113 is positioned within the substrate support 111. As seen in FIG. 2, the heater element 113 produces heat 206 (e.g., through resistive heating), and the heat 206 is directed upwards towards the substrate 110. As a result, the heater element 113 heats the substrate 110.

One or more electrodes 112 are positioned within the substrate support 111. In the example of FIG. 2, the substrate support 111 is part of a bipolar ESC assembly and includes a first electrode 112A and a second electrode 112B. The first electrode 112A and the second electrode 112B may be positioned between the heater element 113 and the top surface 200 of the substrate support 111. Generally, the first electrode 112A and the second electrode 112B are positioned between the heater element 113 and the first portion 201 of the top surface 200. Portions of the first electrode 112A and portions of the second electrode 112B may extend beyond the edge of the first portion 201 of the top surface 200 such that these portions of the first electrode 112A and the second electrode 112B are positioned between the heater element 113 and the second portion 202 of the top surface 200. As a result, the first electrode 112A and the second electrode 112B are generally positioned beneath the first portion 201, but portions of the first electrode 112A and portions of the second electrode 112B may be positioned beneath the second portion 202.

A conductive ring 204 is positioned within the substrate support 111. Generally, the conductive ring 204 is positioned between the second portion 202 of the top surface 200 and the first and second electrodes 112A and 112B. Portions of the conductive ring 204 may extend beyond an inner edge of the second portion 202 such that these portions of the conductive ring 204 are positioned between the first portion 201 of the top surface 200 and the first and second electrodes 112A and 112B. As a result, the conductive ring 204 is generally positioned beneath the second portion 202, but portions of the conductive ring may be positioned beneath the first portion 201.

The conductive ring 204 may be formed using any conductive material. For example, the conductive ring 204 may include molybdenum. In some embodiments, the conductive ring 204 is formed using a conductive mesh that includes conductive segments interlaced into a mesh structure.

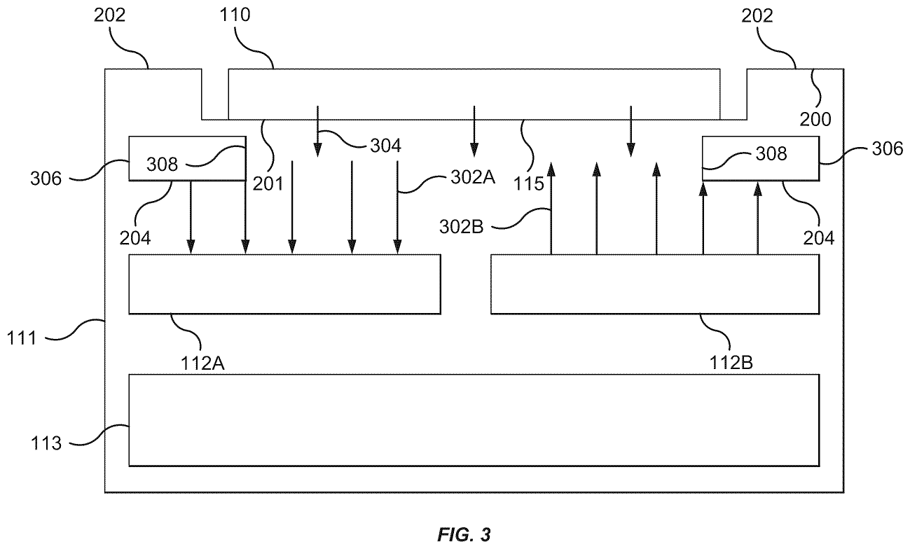

FIG. 3 illustrates a cross-section of an example substrate support 111 in the processing chamber 100 of FIG. 1, according to one embodiment. In the example of FIG. 3, the first and second electrodes 112A and 112B are producing electric fields 302A and 302B, respectively, towards the top surface 200. DC power may be directed to the first electrode 112A and the second electrode 112B, which may cause the first electrode 112A to produce the electric field 302A and the second electrode 112B to produce the electric field 302B. Although FIG. 3 uses arrows to show the electric fields 302A and 302B, the first and second electrodes 112A and 112B may produce electric fields 302A and 302B of any magnitude and polarity. For example, the electric fields 302A and 302B may have opposite polarities.

The electric fields 302A and 302B generate an electrostatic force 304 that pulls the substrate 110 towards the receiving surface 115 of the first portion 201 of the top surface 200. In this manner, the first and second electrodes 112A and 112B may secure the substrate 110 to the substrate support 111, which may keep the substrate 110 from shifting or moving during processing.

As seen in FIG. 3, the conductive ring 204 shields portions of the substrate support 111 from the electric fields 302A and 302B produced by the first and second electrodes 112A and 112B. The conductive ring 204 includes an outer edge 306 and an inner edge 308. The outer edge 306 may be positioned beneath the second portion 202 of the top surface 200, and the inner edge 308 may be positioned beneath the first portion 201 of the top surface 200. Thus, the conductive ring 204 is positioned above a portion of the first electrode 112A and a portion of the second electrode 112B. The electric fields 302A and 302B that are produced by these portions of the first and second electrodes 112A and 112B are directed towards the conductive ring 204. The conductive ring 204 may then reduce the magnitude of the electric fields 302A and 302B. As a result, the second portion 202 and the portions of the first portion 201 positioned above the conductive ring 204 experience a reduced electric field, which may reduce the ion bombardment on these portions of the top surface 200. Consequently, the conductive ring 204 reduces the damage to the second portion 202 of the top surface 200 during processing.

The conductive ring 204 may not shield a majority of the first portion 201 of the top surface (e.g., the receiving surface 115). As a result, even with the conductive ring 204 present, the electric fields 302A and 302B may still generate the electrostatic force 304 that secures the substrate 110 to the receiving surface 115.

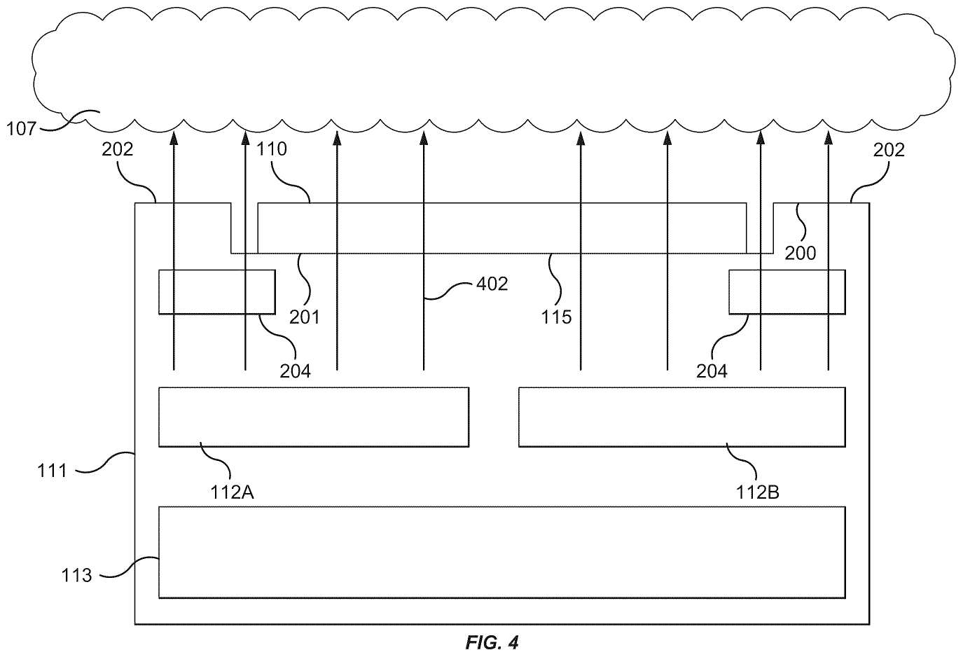

FIG. 4 illustrates a cross-section of an example substrate support 111 in the processing chamber 100 of FIG. 1, according to one embodiment. As seen in FIG. 4, RF power may also be directed to the first and second electrodes 112A and 112B. The first and second electrodes 112A and 112B then deliver RF power 402 towards the top surface 200 of the substrate support 111. The RF power 402 may pass through the conductive ring 204, the top surface 200, and/or the substrate 110 and ignite the plasma 107 in the processing chamber. As a result, the conductive ring 204 does not shield portions of the top surface 200 from RF power delivered by the first and second electrodes 112A and 112B.

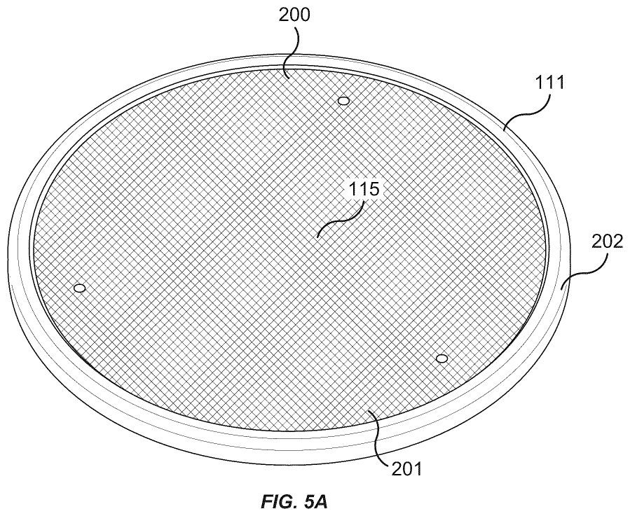

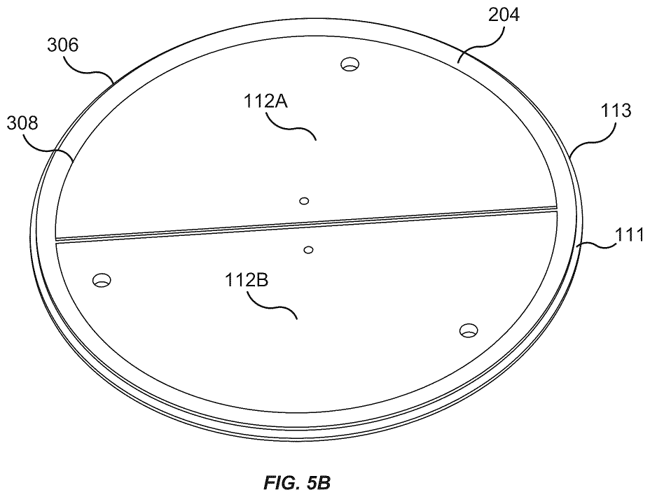

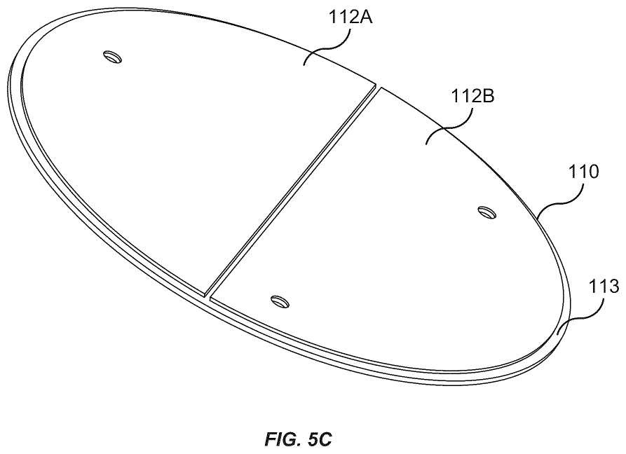

FIG. 5A illustrates an example substrate support 111 in the processing chamber 100 of FIG. 1, according to one embodiment. Specifically, FIG. 5 shows the top surface 200 of the substrate support 111. As seen in FIG. 5, the top surface 200 includes a first portion 201 and a second portion 202. The first portion 201 may form an inner area of the top surface 200, and the second portion 202 may form an outer area of the top surface 200 around the inner area. The first portion 201 and the second portion 202 may be concentric areas. Additionally, the receiving surface 115 may be part of the first portion 201. In some embodiments, the second portion 202 may form a ridge that extends above the first portion 201 such that the second portion 202 provides a boundary that prevents a substrate positioned on the first portion 201 from moving or shifting beyond the second portion 202. Although the substrate support 111 is shown as a circular structure, the substrate support 111 may be of any shape.

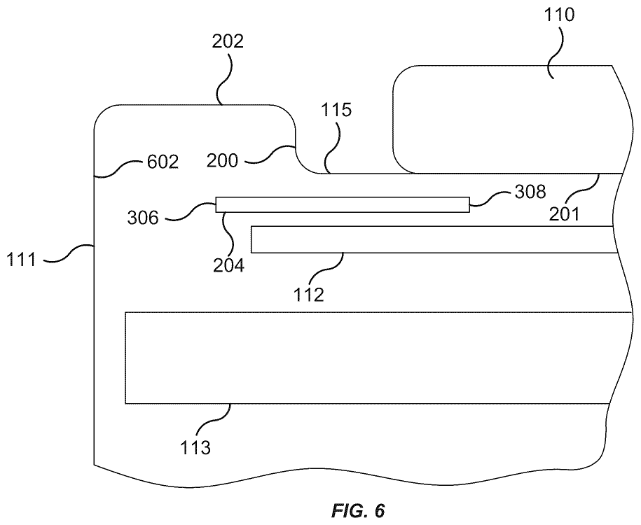

FIG. 5B illustrates example components of a substrate support 111 in the processing chamber 100 of FIG. 1, according to one embodiment. Generally, FIG. 6 shows components of the substrate support 111 beneath the top surface of the substrate support 111 from the perspective shown in FIG. 5. As seen in FIG. 6, the heater element 113, the first and second electrodes 112A and 112B, and the conductive ring 204 are positioned within the substrate support 111. The heater element 113 is positioned beneath the first and second electrodes 112A and 112B, and the first and second electrodes 112A and 112B are positioned beneath the conductive ring 204.

The conductive ring 204 is positioned above the first and second electrodes 112A and 112B, and the conductive ring 204 includes an outer edge 306 and an inner edge 308. The outer edge 306 and the inner edge 308 define a width of the conductive ring 204. As seen in FIG. 6, the conductive ring 204 has a width that covers an outer area of the first and second electrodes 112A and 112B or an outer area of the substrate support. As a result, the conductive ring 204 does not cover a majority of the area of the first and second electrodes 112A and 112B.

When referenced with FIG. 5, it can be seen that the conductive ring 204 is positioned beneath the second portion 202 of the top surface 200 of the substrate support 111. The conductive ring 204 is positioned between the first and second electrodes 112A and 112B and the second portion 202 of the top surface 200 of the substrate support 111. As a result, the conductive ring 204 shields the second portion 202 of the top surface 200 of the substrate support 111 from the electric fields produced by the first and second electrodes 112A and 112B. Consequently, the electric field present at or above the second portion 202 of the top surface 200 may have a reduce magnitude relative to the electric field present at or above the first portion 201 of the top surface 200 or at or above the receiving surface 115. In this manner, the conductive ring 204 reduces ion bombardment on the second portion 202 of the top surface 200, which reduces damage to the second portion 202 of the top surface 200, in certain embodiments.

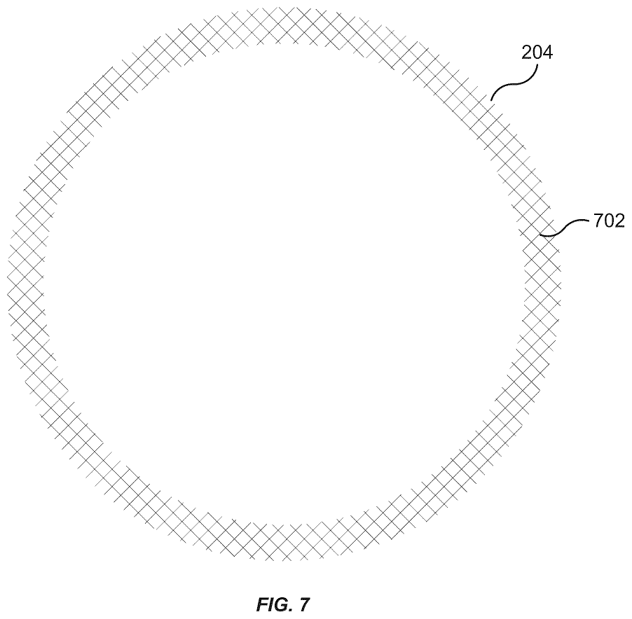

FIG. 5C illustrates example components of a substrate support 111 in the processing chamber 100 of FIG. 1, according to one embodiment. Generally, FIG. 7 shows the components shown in FIG. 6 with the conductive ring 204 removed. As seen in FIG. 7, the first and second electrodes 112A and 112B are positioned on the heater element 113. The heater element 113 may be a circular disc, and the first and the second electrodes 112A and 112B may be semicircular discs positioned on the heater element 113. An outer area of the heater element 113 may extend beyond outer edges of the first and second electrodes 112A and 112B.

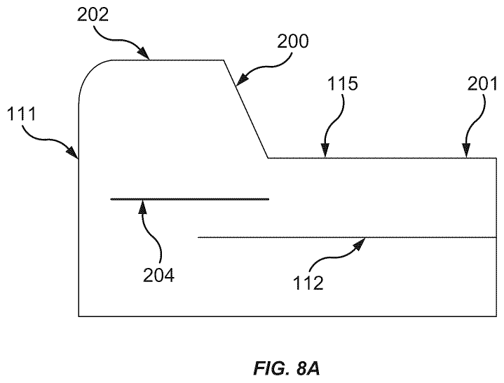

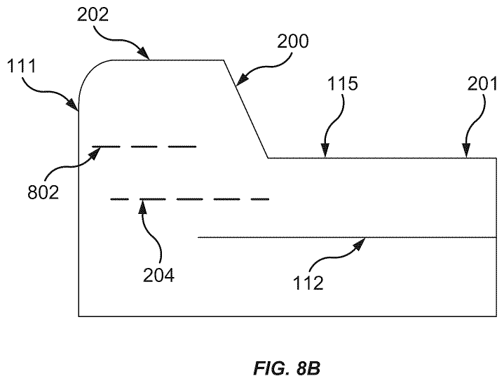

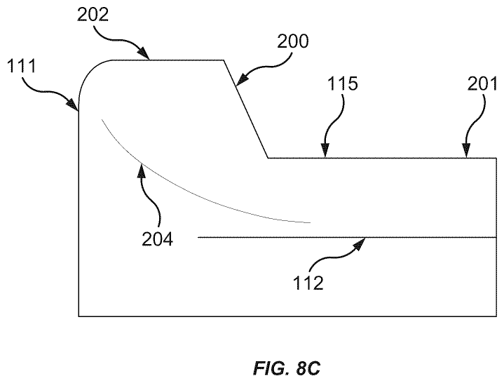

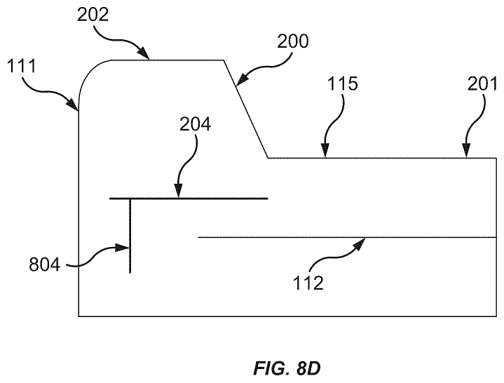

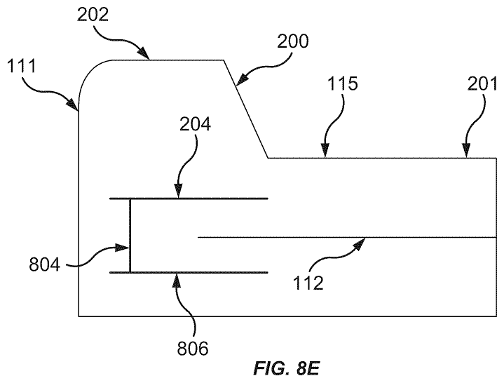

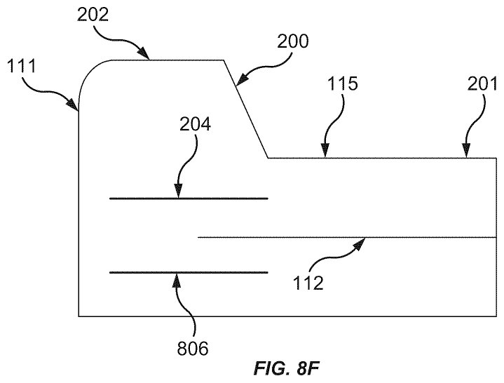

FIG. 6 illustrates a cross-section of a portion of an example substrate support 111 in the processing chamber 100 of FIG. 1, according to one embodiment. As seen in FIG. 8, the substrate support 111 includes the top surface 200. The top surface 200 includes the first portion 201 and the second portion 202 connected to the first portion 201. Generally, the first portion 201 forms an inner area of the top surface 200, and the second portion 202 forms an outer area of the top surface 200 around the inner area. Additionally, the first portion 201 includes the receiving surface 115, and the substrate 110 is positioned on the receiving surface 115. Moreover, the second portion 202 extends upwards higher than the first portion 201 forming an outer boundary that keeps the substrate 110 from moving beyond the second portion 202.

The heater element 113, the electrode 112, and the conductive ring 204 are positioned within the substrate support 111. The electrode 112 is positioned between the heater element 113 and the top surface 200, and the conductive ring 204 is positioned between the electrode 112 and the top surface 200. As seen in FIG. 8, the conductive ring 204 includes an outer edge 306 and an inner edge 308. The inner edge 308 may be positioned between the electrode 112 and the first portion 201. The outer edge 306 may be positioned beneath the second portion 212, between the electrode 112 and the second portion 212. Additionally, the outer edge 306 may be positioned beyond the electrode 112 such that the outer edge 306 of the conductive ring 204 is positioned closer to an outer edge 602 of the substrate support 111 than the electrode 112. A portion of the electrode 112 also extends beneath the second portion 212. As a result of the positioning of the electrode 112 and the conductive ring 204, the conductive ring 204 shields the second portion 202 from the electric field produced by the electrode 112.

There may be any spacing between the heater element 113, the electrode 112, and the conductive ring 204. For example, the conductive ring 204 may be positioned closer to the electrode 112 than the electrode 112 is positioned to the heater element 113. Stated differently, there may be a greater distance between the electrode 112 and the heater element 113 than the distance between the conductive ring 204 than the electrode 112. As another example, the heater element 113 may be positioned closer to the electrode 112 than the electrode 112 is positioned to the conductive ring 204.

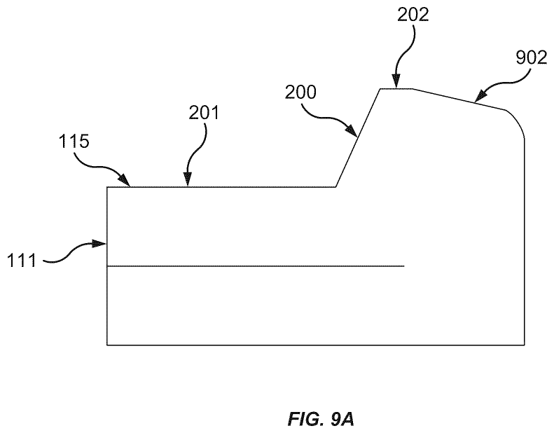

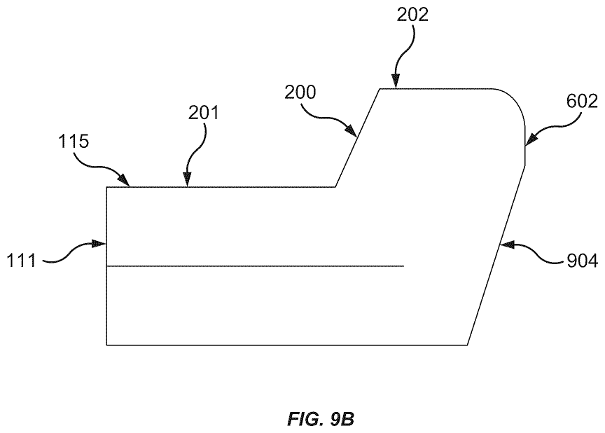

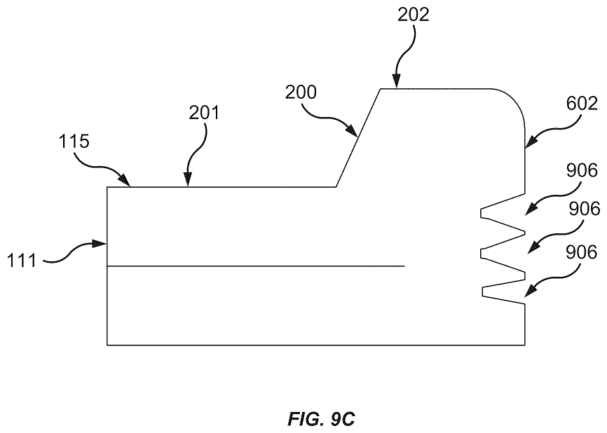

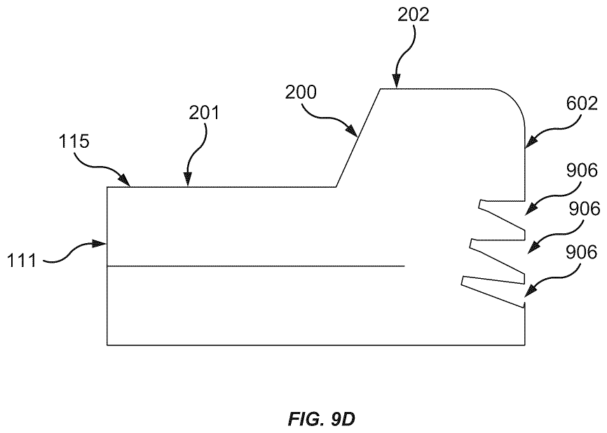

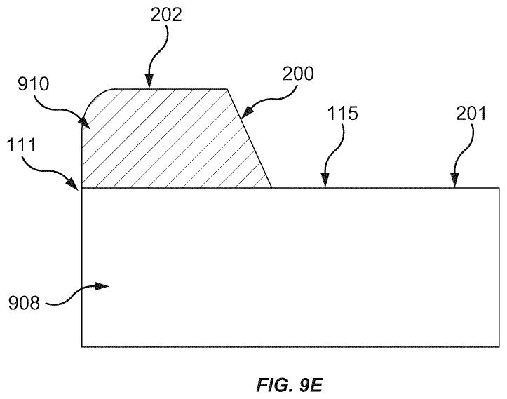

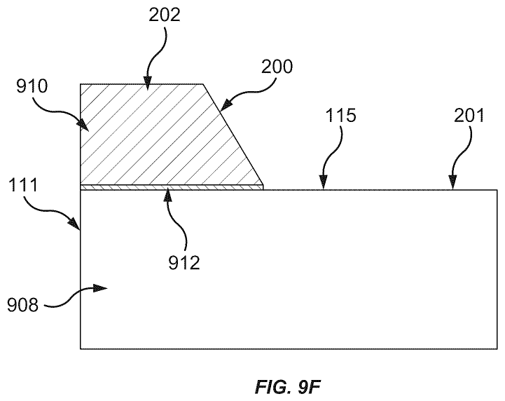

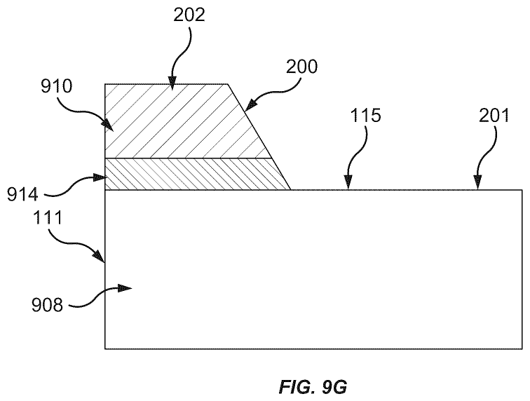

FIG. 7 illustrates an example conductive ring 204 of a substrate support 111 in the processing chamber 100 of FIG. 1, according to one embodiment. As seen in FIG. 9, the conductive ring 204 may be formed using a conductive mesh 702 that includes interlaced conductive traces or segments. By interlacing the conductive traces or segments, the conductive traces or segments may define cavities in the conductive ring 204. The conductive traces or segments may shield portions of the substrate support 111 from electric fields produced by electrodes in the substrate support 111 when the conductive ring 204 is positioned within the substrate support 111.

In other embodiments, the substrate support 111 may include any number of conductive rings 204, and each conductive ring 204 may have any shape or size. FIGS. 8A through 8F illustrate other example arrangements for the conductive ring 204.

FIG. 8A illustrates a cross-section of a portion of an example substrate support 111 in the processing chamber 100 of FIG. 1, according to one embodiment. As seen in FIG. 8A, the conductive ring 204 is positioned within the substrate support 111 between the electrode 112 and the second portion 202 of the top surface 200. The conductive ring 204 is formed using a solid piece of conductive material (e.g., metal) rather than with a mesh. The conductive ring 204 may be positioned in the substrate support 111 in a similar position as shown in previous embodiments. As a result, the conductive ring 204 may shield the second portion 202 from the electric field produced by the electrode 112, which may reduce damage to the second portion 202 during processing.

FIG. 8B illustrates a cross-section of a portion of an example substrate support 111 in the processing chamber 100 of FIG. 1, according to one embodiment. As seen in FIG. 8B, the conductive ring 204 is positioned within the substrate support 111 between the electrode 112 and the second portion 202 of the top surface 200. The conductive ring 204 is formed using a conductive mesh. Additionally, a second conductive ring 802 is positioned within the substrate support 111. The conductive ring 802 is positioned between the conductive ring 204 and the second portion 202 of the top surface 200. Additionally, the conductive ring 802 may be positioned higher than the receiving surface 115 on which a substrate is positioned. The conductive ring 802 may have a thickness of 100 micrometers to 1 millimeter. In some embodiments, the second conductive ring 802 further shields the second portion 202 from the electric field produced by the electrode 112, which may reduce damage to the second portion 202 during processing.

FIG. 8C illustrates a cross-section of a portion of an example substrate support 111 in the processing chamber 100 of FIG. 1, according to one embodiment. As seen in FIG. 8C, the conductive ring 204 is positioned in the substrate support 111 between the electrode 112 and the second portion 202 of the top surface 200. The conductive ring 204 has a curved cross section such that the conductive ring 204 may be similar to a bowl with a hole in the bottom of the bowl. Due to the curved shape of the conductive ring 204, the conductive ring 204 may extend towards the second portion 202 of the top surface 200 at one end. As a result, the conductive ring 204 may shield the second portion 202 from the electric field produced by the electrode 112, which may reduce damage to the second portion 202 during processing.

FIG. 8D illustrates a cross-section of a portion of an example substrate support 111 in the processing chamber 100 of FIG. 1, according to one embodiment. As seen in FIG. 8D, a portion of the conductive ring 204 is positioned in the substrate support 111 between the electrode 112 and the second portion 202 of the top surface 200. Additionally, the conductive ring 204 includes a portion 804 that extends from the conductive ring 204 and away from the second portion 202 and past the electrode 112. The portion 804 may have a thickness or height of 1 millimeter to 10 millimeters. Additionally, the portion 804 may be formed using a mesh or a solid piece of conductive material. As a result, the portion 804 alters the portions of the electric field produced by the electrode 112 that extend towards a side of the substrate support 111 (e.g., by reducing the magnitude of this electric field). Consequently, the electric field is less likely to extend past the side of the substrate support 111 and upwards towards the processing volume, which may reduce damage to the second portion 202 during processing.

FIG. 8E illustrates a cross-section of a portion of an example substrate support 111 in the processing chamber 100 of FIG. 1, according to one embodiment. As seen in FIG. 8E, a portion of the conductive ring 204 is positioned in the substrate support 111 between the electrode 112 and the second portion 202 of the top surface 200. Additionally, the conductive ring 204 includes a portion 804 that extends from the conductive ring 204 and away from the second portion 202 and past the electrode 112, and the conductive ring 204 includes a portion 806 that extends from the portion 804 and towards the electrode 112 such that the electrode 112 is positioned between the conductive ring 204 and the portion 806. There may be more than ten micrometers between the receiving surface 115 and the conductive ring 204. Additionally, there may be ten micrometers between the electrode 112 and the conductive ring 204 and/or between the electrode 112 and the portion 806. As a result, the portions 804 and 806 alter the portions of the electric field produced by the electrode 112 that extend downwards and/or towards a side of the substrate support 111 (e.g., by reducing the magnitude of this electric field). Consequently, the electric field is less likely to extend past the side of the substrate support 111 and upwards towards the processing volume, which may reduce damage to the second portion 202 during processing.

FIG. 8F illustrates a cross-section of a portion of an example substrate support 111 in the processing chamber 100 of FIG. 1, according to one embodiment. As seen in FIG. 8F, a portion of the conductive ring 204 is positioned in the substrate support 111 between the electrode 112 and the second portion 202 of the top surface 200. Additionally, the conductive ring 204 includes a portion 806 that extends from the portion 804 and towards the electrode 112 such that the electrode 112 is positioned between the conductive ring 204 and the portion 806. As a result, the portion 806 effectively forms a second conductive ring in the substrate support 111. As a result, the conductive ring 204 and the portion 806 alter the portions of the electric field produced by the electrode 112 that extend downwards (e.g., by reducing the magnitude of this electric field). For example, the conductive ring 204 and the portion 806 may effectively funnel the electric field towards a portion of the side of the substrate support 111. Consequently, the electric field is less likely to extend past the side of the substrate support 111 and upwards towards the processing volume, which may reduce damage to the second portion 202 during processing.

Additionally or alternatively, the shape, structure, or material of the substrate support may also include features that reduce the electric field that extends past the substrate support. FIGS. 9A through 9G illustrate some example designs for the substrate support 111. For clarity, the conductive ring is not illustrated in these figures.

FIG. 9A illustrates a cross-section of a portion of an example substrate support 111 in the processing chamber 100 of FIG. 1, according to one embodiment. As seen in FIG. 9A, the substrate support 111 includes a top surface 200 with the second portion 202. The second portion 202 includes a section 902 that is sloped. In the example of FIG. 9A, the section 902 is sloped downwards to a side of the substrate support 111. In some embodiments, a step may be present on the second portion 202 between the section 902 and the first portion 201. The sloped section 902 may further alter the electric field produced by the electrode (e.g., reduce the magnitude of the electric field), which may reduce damage to the second portion 202 during processing.

FIG. 9B illustrates a cross-section of a portion of an example substrate support 111 in the processing chamber 100 of FIG. 1, according to one embodiment. As seen in FIG. 9B, the substrate support 111 includes the outer edge 602 on the side of the substrate support 111. The outer edge 602 includes a section 904 that slopes inwards towards the interior of the substrate support 111. In some embodiments, the slope of the section 904 may be between one degree and seventy degrees. As another example, the angle of the slope may be between ten degrees and forty-five degrees. The sloped section 904 may further alter the electric field produced by the electrode (e.g., reduce the magnitude of the electric field), which may reduce damage to the second portion 202 during processing.

FIG. 9C illustrates a cross-section of a portion of an example substrate support 111 in the processing chamber 100 of FIG. 1, according to one embodiment. As seen in FIG. 9C, the substrate support 111 includes the outer edge 602 on the side of the substrate support 111. There may be grooves 906 formed in the outer edge 602 of the substrate support 111. The outer edge 602 may include any number of grooves 906, and the grooves 906 may have any shape and spacing.

FIG. 9D illustrates a cross-section of a portion of an example substrate support 111 in the processing chamber 100 of FIG. 1, according to one embodiment. As seen in FIG. 9D, the substrate support 111 includes the outer edge 602 on the side of the substrate support 111. There may be grooves 906 formed in the outer edge 602 of the substrate support 111. In the example of FIG. 9D, the grooves 906 may be angled relative to the grooves shown in FIG. 9C.

In the examples of FIGS. 9C and 9D, the grooves 906 may have an aspect ratio (e.g., a ratio of height to width) from between one to ten. The width of a groove 906 may be approximately 100 micrometers, and there may be 5 micrometers between the grooves 906. There may be grooves 906 formed down the outer edge 602 to the base of or past the heater within the substrate support 111. The grooves 906 may be any shape, including conic, trapezoidal, paraboloid, etc. The grooves 906 may be one dimensional or two dimensional. In a two-dimensional arrangement, the lattice may be square, triangular, or any other shape. In some embodiments, there may be grooves formed in the top surface 200 of the substrate support 111.

In certain embodiments, the grooves 906 alter the electric field that passes through the surface of the substrate support 111 in which the grooves 906 are formed. For example, the grooves 906 may reduce the magnitude of the electric field, which may reduce damage to the substrate support 111 during processing.

FIG. 9E illustrates a cross-section of a portion of an example substrate support 111 in the processing chamber 100 of FIG. 1, according to one embodiment. As seen in FIG. 9E, the substrate support 111 includes a first portion 908 and a second portion 910. The first portion 908 may be a body of the substrate support 111 and may house a heater, an electrode, and a conductive ring. The portion 910 is positioned on the first portion 908. The portion 910 may form a ridge that extends above the receiving surface 115. The portion 910 may include the second portion 202 of the top surface 200. The portion 910 may be formed using a different material than the portion 908. For example, the portion 910 may have a different resistivity or thermal conductivity than the portion 908. As a result, the portion 910 may alter the electric field passing through the portion 910. For example, the portion 910 may reduce the magnitude of the electric field, which may reduce damage to the substrate support 111 during processing.

In some embodiments, the transition from the material in the portion 908 to the material in the portion 910 may be graded. For example, the section of the portion 910 that is closer to the portion 908 may include some of the material used to form the portion 908 mixed with the material used to form the portion 910. Near the top surface 200, the portion 910 may include less or none of the material used to form the portion 908. By grading the transition between the materials, physical stresses on the portion 908 and the portion 910 may be reduced, which may reduce cracking and splitting.

FIG. 9F illustrates a cross-section of a portion of an example substrate support 111 in the processing chamber 100 of FIG. 1, according to one embodiment. As seen in FIG. 9F, the substrate support 111 includes a layer 912 positioned between the portion 908 and the portion 910, which may be formed using different materials. The layer 912 may be a metal bonding layer formed using different materials. The layer 912 may reduce the physical stresses on the portion 908 and the portion 910, which may reduce cracking and splitting. In some embodiments, the layer 912 may extend such that a portion of the layer 912 is positioned on the receiving surface 115.

FIG. 9G illustrates a cross-section of a portion of an example substrate support 111 in the processing chamber 100 of FIG. 1, according to one embodiment. As seen in FIG. 9G, the substrate support 111 includes a layer 914 positioned between the portion 908 and the portion 910, which may be formed using different materials. The layer 914 may be a diffusion layer formed using different additives. For example, additives like yttrium and calcium may be used to form the layer 914. The layer 914 may reduce the physical stresses on the portion 908 and the portion 910, which may reduce cracking and splitting. In some embodiments, the layer 914 may extend such that a portion of the layer 914 is positioned on the receiving surface 115.

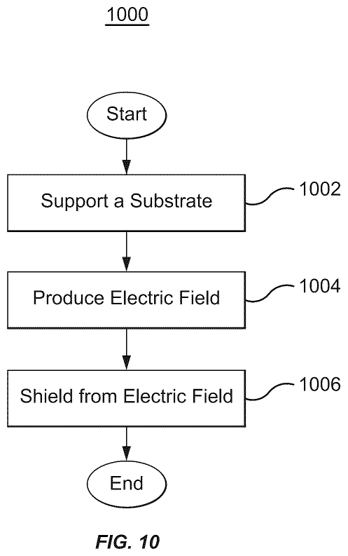

FIG. 10 is a flowchart of an example method 1000 performed by the processing chamber 100 of FIG. 1, according to one embodiment. In certain embodiments, different components of a substrate support (e.g., the substrate support 111 shown in FIG. 1) perform the steps of the method 1000. By performing the method 1000, the substrate support 111 reduces the electric field at or above a portion of the top surface of the substrate support, which reduces damage to the substrate support.

At 1002, the substrate support supports a substrate. The substrate support may include a top surface that includes a first portion and a second portion. The second portion may be positioned around the first portion. The first portion may include a receiving surface, and the substrate may be positioned on the receiving surface such that the first portion supports the substrate.

At 1004, the substrate support produces an electric field. The substrate support includes one or more electrodes positioned beneath the top surface of the substrate support. For example, the substrate support may include two, bipolar electrodes. When DC power is directed to these electrodes, the electrodes may produce electric fields with opposite polarity. The electric fields may generate an electrostatic force that pulls the substrate downwards towards the top surface of the substrate support. In this manner, the electrodes secure the substrate to the substrate support to keep the substrate from moving or shifting during processing.

At 1006, the substrate support shields the second portion of the top surface of the substrate support from the electric fields. The substrate support may include a conductive ring positioned between the electrodes and the top surface of the substrate support. The conductive ring may be formed using a conductive mesh. The conductive ring may be positioned such that the conductive ring is positioned beneath the second portion of the top surface of the substrate support and a portion of the first portion of the top surface of the substrate support. As a result, the conductive ring may reduce the magnitude of the electric field at the second portion of the top surface of the substrate, which may reduce ion bombardment and damage to the second portion.

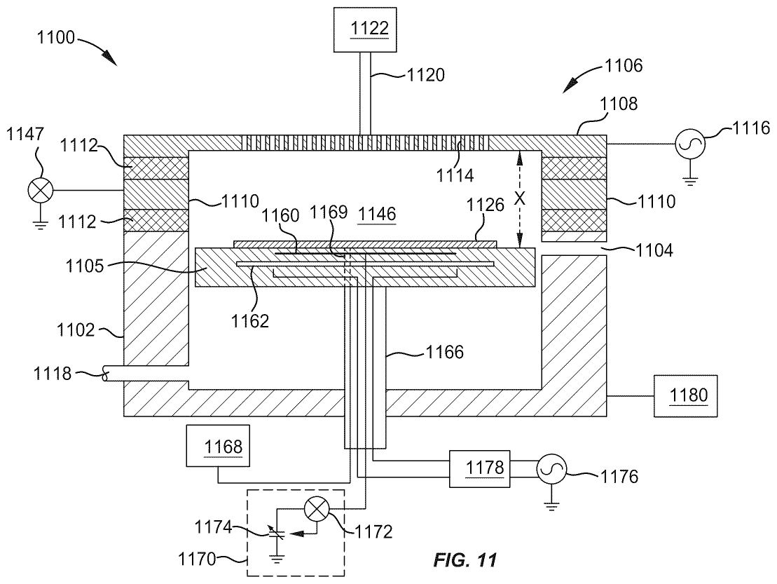

FIG. 11 is a schematic cross sectional view of a process chamber 1100 configured according to various embodiments of the present disclosure. The process chamber 1100 is a PECVD system, but any other process chamber may fall within the scope of the embodiments, including other plasma deposition chambers. By utilizing, in particular, a PECVD system, the cycle time of the deposition processes is reduced, resulting in higher throughput. The process chamber 1100 includes a chamber body 1102, a lid assembly 1106, and a substrate support 1105. The lid assembly 1106 is disposed at an upper end of and is supported by the chamber body 1102, and the substrate support 1105 is at least partially disposed within the chamber body 1102. The chamber body 1102, lid assembly 1106, and substrate support 1105 together define a processing volume 1146 within the process chamber 1100 in which a substrate 1126 may be processed. The processing volume 1146 may be accessed through a port 1104 formed in the chamber body 1102 that facilitates transfer of a substrate into and out of the processing volume 1146 of the process chamber 1100.

The lid assembly 1106 includes a gas distributor 1108, a modulation electrode 1110, and insulators 1112. In some embodiments, the modulation electrode 1110 is optional. The insulator 1112, which may be a dielectric material such as a ceramic or metal oxide, for example aluminum oxide and/or aluminum nitride. The insulator 1112 contacts the modulation electrode 1110 and separates the modulation electrode 1110 electrically and thermally from the gas distributor 1108 and from the chamber body 1102. The gas distributor 1108 (e.g., showerhead) has passages 1114 therethrough for admitting process gas into the processing volume 1146. A pair of insulators (e.g., annular insulators) are disposed between the gas distributor 1108 and the modulation electrode 1110. The modulation electrode 1110 is annular and circumscribes the processing volume 1146. The modulation electrode 1110 is optional, and may be omitted.

Process gases (e.g., one or more precursor and one or more inert carrier gas) may be provided through the conduit 1120 from a gas source 1122 to be introduced into the process chamber 1100. The processing gas from the conduit 1120 enters the processing volume 1146 through the passages 1114 in the gas distributor 1108 such that the processing gas is uniformly distributed in the processing volume 1146. In one embodiment, the passages 1114 in the gas distributor 1108 may be radially distributed and gas flow to each of the passages 1114 may be separately controlled to further facilitate gas uniformity within the processing volume 1146.

The processing gases can be evacuated from the processing volume 1146 through an outlet 1118 which may be located at any convenient location along the chamber body 1102. In some embodiments, the outlet 1118 may be associated with a vacuum pump (not shown) fluidly coupled to the processing volume 1146. The vacuum pump may be part of a gas and pressure control system of the processing chamber 1100. The gas and pressure control system maintains the process volume at a pressure of about 3 Torr to about 50 Torr.

In some embodiments, which may be combined with other embodiments, portions of the gas distributor 1108 may be heated using a resistive heater (not shown) or thermal fluid disposed in a conduit (not shown) through a portion of the gas distributor 1108 or otherwise in direct contact or thermal contact with the gas distributor 1108. The conduit may be disposed through an edge portion of the gas distributor 1108 to avoid disturbing the gas flow function of the gas distributor 1108. Heating the edge portion of the gas distributor 1108 may be useful to reduce the tendency of the edge portion of the gas distributor 1108 to be a heatsink within the process chamber 1100.

In some embodiments, which may be combined with other embodiments, the walls of the chamber body 1102 may also be heated to similar effect. Heating the chamber surfaces exposed to the plasma also minimizes deposition, condensation, and/or reverse sublimation on the chamber surfaces, reducing the cleaning frequency of the chamber and increasing mean cycles per clean. Higher temperature surfaces also promote dense deposition that is less likely to produce particles that fall onto a substrate. Thermal control conduits with resistive heaters and/or thermal fluids (not shown) may be disposed through the chamber walls to achieve thermal control of the chamber walls. Temperature of all surfaces may be controlled by a controller.

The gas distributor 1108 is coupled to a RF power source 1116, such as a RF generator, as shown in FIG. 11. In other embodiments, the gas distributor 1108 may be coupled to ground. The RF power source 1116 is electrically connected to the gas distributor 1108 and is configured to apply a RF potential to the gas distributor 1108 to facilitate the generation of plasma in the interior processing volume 1146.

The RF power source 1116 may be a high frequency RF power source (“HFRF power source”) capable of generating an HFRF power (e.g., at a frequency of about 110 MHz to about 40 MHz, e.g., about 20 MHz to about 22 MHz, about 22 MHz to about 24 MHz, about 24 MHz to about 26 MHz, about 26 MHz to about 28 MHz, or about 28 MHz to about 30 MHz). The HFRF power source can be designed for use with a fixed match or automatch and can regulate the power delivered to the load, eliminating concerns about forward and reflected power. The automatch may cover multiple impedance ranges. In other embodiments, the RF power source 1116 may be a low frequency RF power source (“LFRF power source”) capable of generating an LFRF power (e.g., at a frequency of about 350 kHz to about 2 MHz). The process chamber 1100 includes a HFRF power source and a LFRF power source to enable pulsing of RF and LF power simultaneously.

Without being bound by theory, increasing a HFRF power source can provide an increase in the radical production rate (e.g., C₂H production rate and H production rate, when using acetylene as a precursor) and neutral production rate, thereby producing a more conformal and/or uniform carbon gapfill in trenches between one or more features, and reducing pattern loading effects.

Without being bound by theory, the LFRF power may increase the ion energy distribution function (IEDF) and decreases the ion angular distribution function (IADF), enabling increased ion flux during the generation of the plasma in the interior processing volume 1146 and enabling increased ion directionality. At lower frequencies, ions experience a more constant electric field over each cycle, enabling the ions to gain more energy and uniformity and resulting in a narrower IEDF. At higher frequencies, the electric field oscillates rapidly, causing ions to experience a varying field as they traverse the sheath. This results in a broader IEDF and leads to a wider range of energies and complex energy transfer dynamics. This enables lower energy peaks, favoring a radical driven process.

At lower frequencies, ions have more time to respond to the electric field direction, resulting in a more collimated angular distribution. The ions are more likely to travel straight towards the electrode, leading to a narrow IADF. At higher frequencies, the ions experience changes in direction due to the rapidly changing electric field, which may cause ions to be deflected or scattered, broadening the IADF and reducing the directionality of the ion beam. Narrower IADF helps with directional fill/etch, while a broader IADF helps with conformal fill. Therefore, a combination of HFRF and LFRF enables an increase in the ion production and the ion directionality. Without being bound by theory, an ion driven regime (e.g., IEDF) reduces a deposition rate and decreases sheath potential. The sheath potential is the voltage difference between the plasma generated in the process chamber 1100 and the substrate 1126. Decreasing the sheath potential in an ion driven regime, thus, decreases the deposition rate. At higher frequencies (e.g., HFRF), the sheath responds quickly to an oscillating electric field. The rapid oscillations restricts ion movement. This rapid response typically results in a thinner sheath, as ions do not have sufficient time to penetrate deeply into the sheath before the electric field reverses direction. At lower frequencies (e.g., LFRF), the sheath has more time to respond to the oscillating field, allowing ions to further penetrate and resulting in a thicker sheath. The slower oscillation allows ions to move deeper into the sheath. The sheath thickness increases as ions travel further into the sheath, causing it to expand, as the spatial distribution of positive ions require a larger region to maintain charge balance and accommodate the electric field.

Meanwhile, a radical driven regime (e.g., IADF) increases the deposition rate, as neutral/radical regimes are driven with thermal flux, which is larger than a diffusive flux that drives the ion regime. The diffusive flux, however, enables increased uniformity in gapfill deposition between narrower critical dimension structures and wider critical dimension structures.

By pulsing HFRF and LFRF, the IEDF and IADF are tunable to improve deposition uniformity, reduce the thermal load, increase the ability for thermal management, minimize the charging effects, and enhance the plasma chemistry. A low pulsing frequency enables a broader IEDF and IADF is enabled due to longer off periods, thus enabling more ion energy loss and directional scattering. A high pulsing frequency leads to narrower IEDF and IADF due to shorter off periods, thus maintaining more consistent acceleration and directionality. Pulsing HFRF/LFRF, e.g., from 200 Hz to 110,000 Hz, enables precise control of the duration of the ion/electron behavior. Adjusting pulsing frequency and duty cycle provides a means to control the IEDF and IADF in micro-to milli-level timescales, enabling the tuning of the plasma process in various applications and for gap filling different CDs. By changing the pulsing frequency, duty cycle, and RF frequency, IADF and IEDF can be modulated in short timescales to deposit or etch the CDs and control the lifetime of ions and radicals for the process. Thus, pulsing and duty cycle can be used to modulate between the IADF and IEDF regions in a controlled manner, and to toggle between anisotropic deposition (higher ion regime) and isotropic deposition (higher radical regime) and mimic different pressure regimes.

Pulsing reduces the average power delivered to the substrate 1126, minimizing thermal damage to the substrate 1126. Pulsing also allows the substrate 1126 and surrounding equipment to cool down, preventing overheating. Pulsing enables charge to dissipate during off periods, reducing the risk of surface charging and related defects such as arcing. Further still, the ratio of ion/neutral density enables increased control over the chemical reactions. Using continuous wave (CW) pulsing enables similar phenomena to the pulsing HFRF/LFRF.

Controlling the IADF and IEDF via RF frequency, pulsing, and duty cycle enables the imitation of different pressure regimes. For example, at low pressures, the IEDF has a narrower distribution, and higher and more consistent ion energies due to fewer collisions. Meanwhile, the IADF has a narrower angular distribution, more collimated ion trajectories, and more perpendicular ion strikes on the substrate 1126. These condition can be replicated using LFRF with higher pulsing frequency and duty cycle. The duty cycle may be from about 110% to about 90%, such as about 25% to about 75%, such as about 40% to about 60%.

In another example, at high pressure, the IEDF has a broader distribution and wider range of ion energies due to frequent collisions. Meanwhile, the IADF has a broader angular distribution and more scattered ion trajectory. These conditions can be replicated using HFRF at a higher pulsing frequency and duty cycle. The duty cycle may be from about 110% to about 90%%, such as about 25% to about 75%, such as about 40% to about 60%. In further embodiments, which can be combined with other embodiments, an additional power source 1147 may be added with the RF power source 1116 to provide a dual RF power source to the process chamber 1100. It is contemplated the modulation electrode 1110 and the additional power source 1147 may be omitted.

The substrate support 1105 may be disposed within the process chamber 1100. The substrate support 1105 may support the substrate 1126 during processing. A first electrode 1160 and a second electrode 1162 are disposed in and/or on the substrate support 1105. Further, in some embodiments, a heater element (not shown) may be embedded in the substrate support 1105. The heater element can be operable to controllably heat the substrate support 1105 and the substrate 1126 positioned thereon to a target temperature, such as to maintain the substrate 1126 at a temperature in a range from about 350 degrees Celsius to about 500 degrees Celsius. The substrate support 1105 is a distance X from the gas distributor. The distance X is about 250 mils to about 750 mils, such as about 500 mils.

The substrate support 1105 is coupled to a shaft 1166 for support. The shaft 1166 can provide a conduit from a gas source 1168 and electrical and temperature monitoring leads (not shown) between the substrate support 1105 and other components of the process chamber 1100. In some examples, a purge gas may be provided from the gas source 1168 to the backside of the substrate 1126 through one or more purge gas inlets 1169 connected to the substrate support 1105. The purge gas flowed toward the backside of the substrate 1126 can help prevent particle contamination caused by deposition on the backside of the substrate 1126. The purge gas may also be used as a form of temperature control to cool the backside of the substrate 1126. Although not illustrated, the shaft 1166 may be coupled to an actuator (not shown) which extends through a centrally-located opening formed in a bottom of the chamber body 1102. The actuator may be flexibly sealed to the chamber body 1102 by bellows (not shown) that prevent vacuum leakage from around the shaft 1166. The actuator can allow the substrate support 1105 to be moved vertically within the chamber body 1102 between a process position and a lower, transfer position. The transfer position is slightly below the port 1104 in the chamber body 1102. In operation, the substrate support 1105 may be elevated to a position in close proximity to the lid assembly 1106 for processing.

The first electrode 1160 may be embedded within the substrate support 1105 or coupled to a surface of the substrate support 1105. The first electrode 1160 may be a plate, a perforated plate, a mesh, a wire screen, or any other distributed arrangement. The first electrode 1160 may be a tuning electrode and may be coupled to a tuning circuit 1170. The tuning circuit 1170 may have an electronic sensor 1172 and an electronic controller, such as a variable capacitor 1174 electrically connected between the first electrode 1160 and an electrical ground. The electronic sensor 1172 may be a voltage or current sensor and may be coupled to the variable capacitor 1174 to provide further control over plasma conditions in the processing volume 1146.

The second electrode 1162, which may be a bias electrode and/or an electrostatic chucking electrode, may be coupled to the substrate support 1105. The second electrode 1162 may be coupled to a bias power source 1176 through an impedance matching circuit 1178. The bias power source 1176 may be DC power, pulsed DC power, RF power, pulsed RF power, or a combination thereof (e.g., pulsing HFRF or continuous wave HFRF).

In operation, the substrate 1126 is disposed on the substrate support 1105, and process gases are flowed through the lid assembly 1106 according to any desired flow plan. Electric power is coupled to the gas distributor to establish a plasma in the processing volume 1146. The substrate 1126 may be subjected to an electrical bias using the bias power source 1176, if desired.

A controller 1180 is coupled to the process chamber 1100. The controller 1180 controls various processing parameters of the process chamber 1100, such as the gas flow rate, the temperature of the substrate 1126, the position of the substrate 1126, and other parameters. The controller 1180 controls the various processing parameters by controlling various components of the process chamber 1100, such as the RF power source 1116, the additional power source 1147, the tuning circuits 1144 and 1170, the shaft 1166, the gas source 1122, and other components.

The subject matter of the present application may be used in the chamber 1100 of FIG. 11, as well as other chambers (e.g., the chamber 100 of FIG. 1). The insulator 1112, the power source 1147, and/or the modulation electrode 1110 may be optional components, and some embodiments may not include one or more of these components.

In summary, the ESC assembly includes a conductive ring 204 that shields portions of the ESC from electric fields produced by one or more electrodes in the ESC. Generally, the conductive ring 204 is positioned within the substrate support 111 in the ESC between the electrodes 112 that produce the electric fields and the top surface of the substrate support 111 that supports the substrate 110. The conductive ring 204 may extend beyond the edges of the electrodes 112 and closer to a side edge of the substrate support 111. As a result, the conductive ring 204 provides a barrier that shields the portion of the top surface of the substrate support 111 that extends beyond the edge of the substrate from the electric fields produced by the electrodes 112.

Embodiments of the disclosure have been described above with reference to specific embodiments and numerous specific details are set forth to provide a more thorough understanding of the disclosure. Persons skilled in the art, however, will understand that various modifications and changes may be made thereto without departing from the broader spirit and scope of the disclosure. The foregoing description and drawings are, accordingly, to be regarded in an illustrative rather than a restrictive sense.

While the foregoing is directed to embodiments of the present disclosure, other and further embodiments of the disclosure may be devised without departing from the basic scope thereof, and the scope thereof is determined by the claims that follow.

1. An electrostatic chuck comprising:
a substrate support comprising a surface, wherein the surface comprises (i) a first portion arranged to support a substrate and (ii) a second portion positioned around the first portion;
a first electrode positioned within the substrate support, wherein the first electrode is arranged to produce a first electric field; and
a conductive ring positioned within the substrate support and between the second portion of the surface and the first electrode, wherein the conductive ring is arranged to shield the second portion from the first electric field.

2. The electrostatic chuck of claim 1, wherein the conductive ring comprises a conductive mesh.

3. The electrostatic chuck of claim 1, further comprising a heater positioned within the substrate support, wherein the first electrode is positioned between the heater and the conductive ring.

4. The electrostatic chuck of claim 3, wherein the conductive ring is positioned closer to the first electrode than the first electrode is positioned to the heater.

5. The electrostatic chuck of claim 1, further comprising a second electrode positioned within the substrate support, wherein the second electrode is arranged to produce a second electric field, wherein the conductive ring is positioned between the second portion of the surface and the second electrode, and wherein the conductive ring is further arranged to shield the second portion from the second electric field.

6. The electrostatic chuck of claim 1, wherein the conductive ring comprises an outer edge and an inner edge, and wherein the inner edge of the conductive ring is positioned between the first portion of the surface and the first electrode.

7. The electrostatic chuck of claim 6, wherein the substrate support comprises an outer edge, and wherein the outer edge of the conductive ring is positioned closer to the outer edge of the substrate support than the first electrode.

8. The electrostatic chuck of claim 7, wherein the outer edge of the conductive ring is positioned between the second portion of the surface and the first electrode.

9. The electrostatic chuck of claim 1, wherein the first electrode is further arranged to deliver radio frequency (RF) power towards the surface, and wherein the conductive ring is further arranged to pass the RF power.

10. A method comprising:
supporting, by a first portion of a surface of a substrate support, a substrate, wherein the surface further comprises a second portion positioned around the first portion;
producing, by a first electrode positioned within the substrate support, a first electric field; and
shielding, by a conductive ring positioned within the substrate support and between the second portion of the surface and the first electrode, the second portion from the first electric field.

11. The method of claim 10, wherein the conductive ring comprises a conductive mesh.

12. The method of claim 10, further comprising heating, by a heater positioned within the substrate support, the substrate, wherein the first electrode is positioned between the heater and the conductive ring.

13. The method of claim 12, wherein the conductive ring is positioned closer to the first electrode than the first electrode is positioned to the heater.

14. The method of claim 10, further comprising:
producing, by a second electrode positioned within the substrate support, a second electric field, wherein the conductive ring is positioned between the second portion of the surface and the second electrode; and
shielding, by the conductive ring, the second portion from the second electric field.

15. The method of claim 10, wherein the conductive ring comprises an outer edge and an inner edge, and wherein the inner edge of the conductive ring is positioned between the first portion of the surface and the first electrode.

16. The method of claim 15, wherein the substrate support comprises an outer edge, and wherein the outer edge of the conductive ring is positioned closer to the outer edge of the substrate support than the first electrode.

17. The method of claim 16, wherein the outer edge of the conductive ring is positioned between the second portion of the surface and the first electrode.

18. The method of claim 10, further comprising:
delivering, by the first electrode, radio frequency (RF) power towards the surface; and
passing, by the conductive ring, the RF power.

19. A processing chamber comprising:
a substrate support positioned within a process volume defined by a chamber body, wherein the substrate support comprises a surface, wherein the surface comprises (i) a first portion arranged to support a substrate within the process volume and (ii) a second portion positioned around the first portion;
a first electrode positioned within the substrate support, wherein the first electrode is arranged to produce a first electric field;
a second electrode positioned within the substrate support, wherein the second electrode is arranged to produce a second electric field; and
a conductive ring positioned within the substrate support and between the second portion of the surface and the first and second electrodes, wherein the conductive ring is arranged to shield the second portion from the first and second electric fields.

20. The processing chamber of claim 19, wherein the conductive ring comprises a conductive mesh.
